(19) United States
(12) Patent Application Publication
(10) Pub. No.: US 2018/0082720 A1
(43) Pub. Date: Mar. 22, 2018

(54) PIPELINED INTERCONNECT CIRCUITRY HAVING RESET VALUES HOLDING CAPABILITIES

(71) Applicant: Altera Corporation, San Jose, CA (US)

(72) Inventor: Frederic Richard, Maidenhead (GB)

(21) Appl. No.: 15/270,485

(22) Filed: Sep. 20, 2016

(51) Int. Cl. G11C 7/10; G06F 13/40; G06F 1/24

(52) U.S. Cl. CPC G11C 7/1012; G11C 7/1072; G06F 1/24; G06F 13/4022

(57) ABSTRACT

An integrated circuit may have pipelined interconnects that includes reset control circuitry, which provide desirable reset values to combinational logic. The pipelined interconnects may include multiple parallel input data paths coupled to the combinational logic. The reset control circuitry may include multiplexers coupled between the pipelined interconnects and the combinational logic for each input data path. The multiplexers may provide the desired reset values to the combinational logic based on control signals from counter and comparison logic circuitry. By comparing path lengths for the input data paths and a timing after reconfiguring the combinational logic, the counter and comparison logic circuitry may provide the correct control signals to the multiplexers during operation after reconfiguring the combinational logic. The number of clock cycles that the counter needs to wait before releasing the control signals may be determined using automated circuit design tools implemented on specialized computing equipment.

### BACKGROUND

This invention relates to integrated circuits and, more particularly, to pipelined interconnect circuitry having reset value holding capabilities on an integrated circuit.

Every transition from one technology node to the next technology node has resulted in smaller transistor geometries and thus potentially more functionality implemented per unit of integrated circuit area. Synchronous integrated circuits have further benefited from this development as evidenced by reduced interconnect and cell delays, which have led to performance increases. However, more recent technology nodes have seen a significant slow-down in the reduction of delays (i.e., a slow-down in the performance increase).

To further increase the performance, solutions such as register pipelining have been proposed, where additional registers are inserted between synchronous elements to help increase operating frequency and throughput. However, because of limited hardware resources, the additional registers may not have a reset function or may not be enabled to output a desired reset value (e.g., user-defined reset value) to downstream synchronous elements.

Situations frequently arise where the downstream synchronous elements require a particular reset value that ensures the operability of the downstream synchronous elements.

It is within this context that the embodiments herein arise.

### SUMMARY

It is appreciated that the present invention can be implemented in numerous ways, such as a process, an apparatus, a system, a device, or a method on a computer readable medium. Several inventive embodiments of the present invention are described below.

In accordance with a first embodiment, an integrated circuit may have logic circuitry and a switching circuit. The switching circuit may selectively provide a reset signal or a data signal to the logic circuit. The integrated circuit may also include a latching circuity that has a programmable reset value and that feeds the data signal to the switching circuit. The integrated circuit may further include a circuit without a programmable reset value that is interposed between the latching circuit and the switching circuit. The circuit may have a fixed reset value. Alternatively, the circuit may not be resettable (e.g., cannot be reset) and will thus start in an unknown state having a potentially variable value. The circuit may include at least one pipeline register. The switching circuit may include a multiplexer. The latching circuit may include a register. The integrated circuit may further include control logic for controlling the switching circuit.

In accordance with a second embodiment, an integrated circuit may include a control circuit and first and second switching circuits. The first switching circuit may receive a signal from a first input path and a reset signal. The control circuit may receive a clock signal. The control circuit may also configure the first switching circuit to pass through the first reset signal for a predetermined number of clock signals. After passing the first reset signal to the first switching circuit for the predetermined number of clock cycles, the control circuit may configure the first switching circuit to pass though the signal from the first input path. The control circuit may count the number of clock cycles that have elapsed for the clock signal. The control circuit may also compare the count to the predetermined number of clock cycles.

Further to the second embodiment, the second switching circuit may receive a signal from a second input path and a second reset signal. The control circuit may configure the second switching circuit to pass through the second reset signal for the predetermined number of clock cycles. After passing the second reset signal to the second switching circuit for the predetermined number of clock cycles, the control circuit may configure the second switching circuit to pass through the signal from the second input path.

Alternatively, the control circuit may configure the second switching circuit to pass through the second reset signal for a given number of clock cycles that is different than the predetermined number of clock cycles. In this scenario, after passing the second reset signal to the second switching circuit for the given number of clock cycles, the control circuit may configure the second switching circuit to pass through the signal form the second input path.

In accordance with a third embodiment, an integrated circuit may include combinational logic (sometimes referred to as “combinatorial logic circuitry”), first and second registers with programmable reset values, first and second multiplexers that receives signals from the respective first and second registers and that also receives respective first and second predetermined reset values. The first circuit may include configurable pipelined routing resources. The configurable pipelined routing resources may include a plurality of series-connected pipeline registers. The integrated circuit may further include a counter that controls the first multiplexer.

Further features of the invention, its nature and various advantages, will be more apparent from the accompanying drawings and the following detailed description of the preferred embodiments.

### BRIEF DESCRIPTION OF THE DRAWINGS

FIG. 1 is a diagram of an illustrative integrated circuit having an exemplary routing topology in accordance with an embodiment.

FIG. 2 is a diagram of an illustrative interconnect circuit with staggered wires in accordance with an embodiment.

FIG. 3 is a diagram of an illustrative pipelined routing resource which uses a register to pipeline a routing signal in accordance with an embodiment.

FIG. 4 is a diagram of a circuit design system that may be used to design integrated circuits in accordance with an embodiment.

FIG. 5 is a diagram of illustrative computer-aided design (CAD) tools that may be used in a circuit design system in accordance with an embodiment.

FIG. 6 is a flow chart of illustrative steps for designing an integrated circuit in accordance with an embodiment.

FIG. 7 is a diagram of pipelined registers that propagates signals from an upstream element to a downstream element.

FIG. 8 is a diagram of an illustrative reset control circuit which uses a multiplexer and a corresponding control logic circuit in accordance with an embodiment.

FIG. 9 is a diagram of an illustrative reset control circuit which uses multiple multiplexers and a corresponding control logic circuit in accordance with an embodiment.

FIG. 10 is a diagram of an illustrative reset control circuit which uses multiple multiplexers and multiple control logic circuits in accordance with an embodiment.

FIG. 11 is a flow chart showing illustrative steps for configuring and operating reset control circuitry in accordance with an embodiment.

### DETAILED DESCRIPTION

The present invention relates to integrated circuits and, more particularly, to pipelined interconnect circuitry with reset value holding capabilities on an integrated circuit.

As the functionality implemented per unit of die area continues to increase, it becomes increasingly challenging for existing routing architectures to support a high speed connection across an integrated circuit die. Thus, situations frequently arise where the critical path between sequential elements spans a large distance across the die.

Solutions such as register pipelining have been proposed to further increase the performance. During register pipelining, additional registers are inserted between synchronous elements which leads to an increase in latency at the benefit of increased clock frequencies and throughput. However, performing register pipelining often involves spending significant time and effort because several iterations of locating performance bottlenecks, inserting or removing registers, and compiling the modified integrated circuit design are usually required.

Therefore, solutions have been proposed that include interconnect circuitry with embedded registers that can be activated through a configuration process. However, the operation of embedded registers within the interconnect circuitry are often simplified to completely or partially exclude reset functionalities.

It may therefore be desirable to improve the reset functionalities of the interconnect circuitry with reset control circuitry, for example by inserting a reset control circuit into a given path of a pipelined interconnect circuit.

It will be recognized by one skilled in the art, that the present exemplary embodiments may be practiced without some or all of these specific details. In other instances, well-known operations have not been described in detail in order not to unnecessarily obscure the present embodiments.

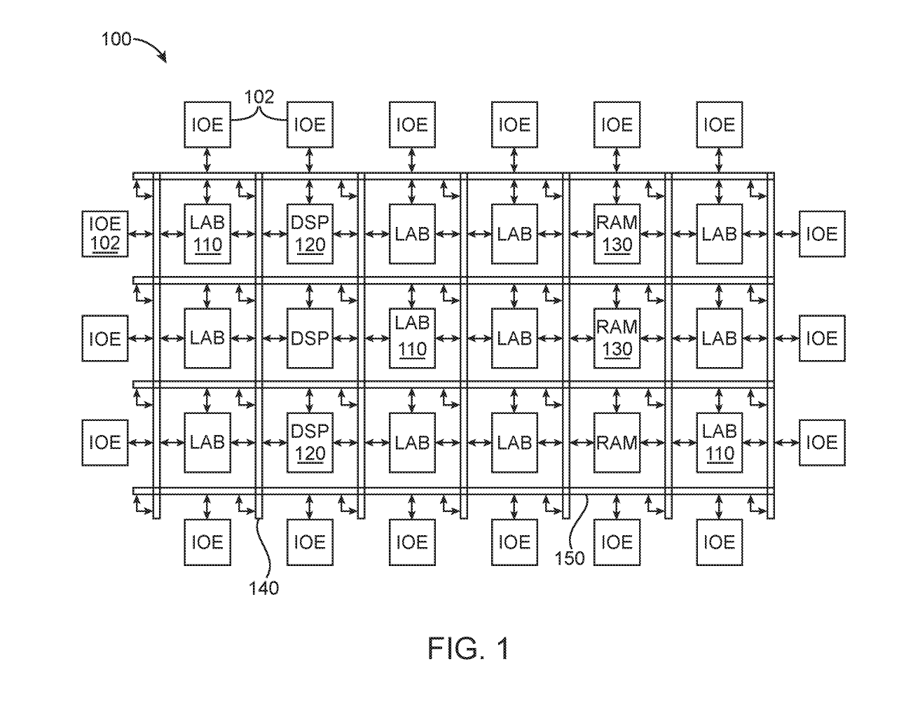

An illustrative embodiment of an integrated circuit such as programmable logic device (PLD) 100 having an exemplary interconnect circuitry is shown in FIG. 1. As shown in FIG. 1, the programmable logic device (PLD) may include a two-dimensional array of functional blocks, including logic array blocks (LABs) 110 and other functional blocks, such as random access memory (RAM) blocks 130 and digital signal processing (DSP) blocks 120, for example. Functional blocks such as LABs 110 may include smaller programmable regions (e.g., logic elements, configurable logic blocks, or adaptive logic modules) that receive input signals and perform custom functions on the input signals to produce output signals.

Programmable logic device 100 may contain programmable memory elements. Memory elements may be loaded with configuration data (also called programming data) using input/output elements (IOEs) 102. Once loaded, the memory elements each provide a corresponding static control signal that controls the operation of an associated functional block (e.g., LABs 110, DSP 120, RAM 130, or input/output elements 102).

In a typical scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory, configuration RAM (CRAM), configuration memory elements, or programmable memory elements.

In addition, the programmable logic device may have input/output elements (IOEs) 102 for driving signals off of PLD and for receiving signals from other devices. Input/output elements 102 may include parallel input/output circuitry, serial data transceiver circuitry, differential receiver and transmitter circuitry, or other circuitry used to connect one integrated circuit to another integrated circuit. As shown, input/output elements 102 may be located around the periphery of the chip. If desired, the programmable logic device may have input/output elements 102 arranged in different ways. For example, input/output elements 102 may form one or more columns of input/output elements that may be located anywhere on the programmable logic device (e.g., distributed evenly across the width of the PLD). If desired, input/output elements 102 may form one or more rows of input/output elements (e.g., distributed across the height of the PLD). Alternatively, input/output elements 102 may form islands of input/output elements that may be distributed over the surface of the PLD or clustered in selected areas.

The PLD may also include programmable interconnect circuitry in the form of vertical routing channels 140 (i.e., interconnects formed along a vertical axis of PLD 100) and horizontal routing channels 150 (i.e., interconnects formed along a horizontal axis of PLD 100), each routing channel including at least one track to route at least one wire. If desired, the interconnect circuitry may include double data rate interconnections and/or single data rate interconnections. A double data rate interconnection may convey twice the amount of data compared to a single data rate interconnection when operated at the same clock frequency.

If desired, routing wires may be shorter than the entire length of the routing channel. A length L wire may span L functional blocks. For example, a length four wire may span four blocks. Length four wires in a horizontal routing channel may be referred to as “H4” wires, whereas length four wires in a vertical routing channel may be referred to as “V4” wires.

Different PLDs may have different functional blocks which connect to different numbers of routing channels. A three-sided routing architecture is depicted in FIG. 1 where input and output connections are present on three sides of each functional block to the routing channels. Other routing architectures are also intended to be included within the scope of the present invention. Examples of other routing architectures include 1-sided, 1½-sided, 2-sided, and 4-sided routing architectures.

In a direct drive routing architecture, each wire is driven at a single logical point by a driver. The driver may be associated with a multiplexer which selects a signal to drive on the wire. In the case of channels with a fixed number of wires along their length, a driver may be placed at each starting point of a wire.

Note that other routing topologies, besides the topology of the interconnect circuitry depicted in FIG. 1, are intended to be included within the scope of the present invention. For example, the routing topology may include wires that travel diagonally or that travel horizontally and vertically along different parts of their extent as well as wires that are perpendicular to the device plane in the case of three dimensional integrated circuits, and the driver of a wire may be located at a different point than one end of a wire. The routing topology may include global wires that span substantially all of PLD 100, fractional global wires such as wires that span part of PLD 100, staggered wires of a particular length, smaller local wires, or any other suitable interconnection resource arrangement.

Furthermore, it should be understood that embodiments of the present invention may be implemented in any integrated circuit. If desired, the functional blocks of such an integrated circuit may be arranged in more levels or layers in which multiple functional blocks are interconnected to form still larger blocks. Other device arrangements may use functional blocks that are not arranged in rows and columns.

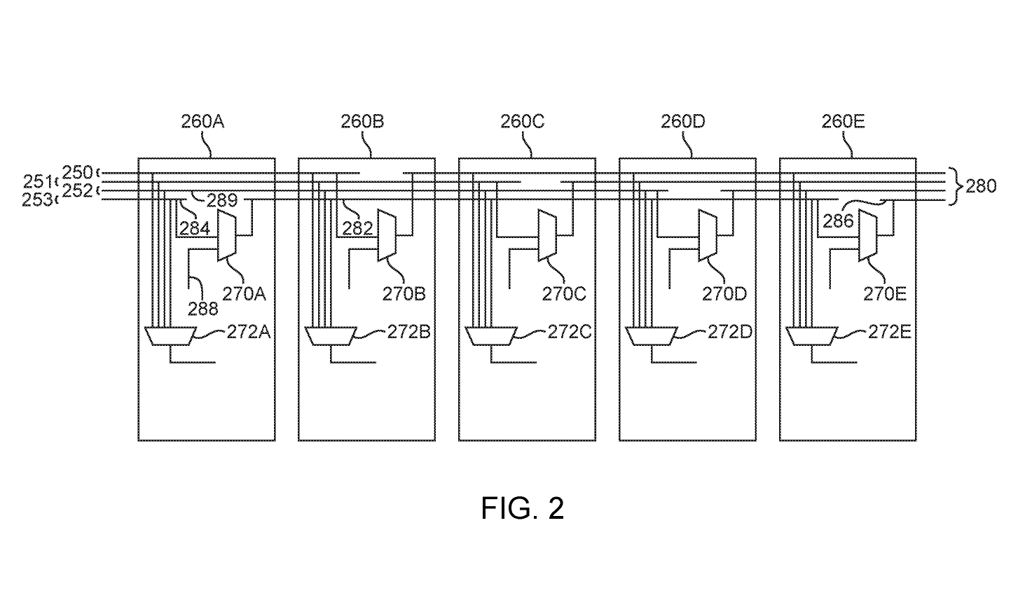

FIG. 2 shows a direct drive horizontal routing channel 280 including a single bundle of wires across functional blocks 260. Each functional block 260 may have a driver (not shown) to drive a signal on a wire that starts in the respective functional block (e.g., wire 286).

Each driver may be associated with a multiplexer such as multiplexer 270. For example, multiplexer 270E may be configured to select a signal to drive on wire 286, and multiplexer 270A may be configured to select a wire that ends in the respective functional block (e.g., wire 284). Connecting a wire that ends in a functional block to a wire that starts in that identical functional block is sometimes also referred to as “wire stitching” or stitching. If desired, tri-state circuits may perform the wire stitching instead of multiplexers 270, which may result in a bi-directional routing channel 280. Alternatively, wires may perform the wire stitching (e.g., by blowing fuses during configuration or by adding wires in a mask-programmable device). In other words, wires may directly connect to other wires to implement a long wire (not shown).

If desired, multiplexer 270E may be configured to select a signal from a different wire. For example, multiplexer 270E may select a signal from a wire driven by a block within functional block 260E. Multiplexer 270E may also select a signal from a wire in another routing channel such as a signal from a wire in a vertical routing channel that ends in the respective functional block (not shown).

Each functional block 260 may include one or more multiplexers 272 (e.g., multiplexer 272A in functional block 260A), which may be configured to route a wire of routing channel 280 to a block within the respective functional block 260.

As shown, each wire of routing channel 280 is unidirectional from left to right and has a length of four. In other words, a wire that starts in functional block 260A will end in the functional block 260E. If desired, routing channel 280 may be bi-directional (e.g., with tri-state buffers performing the wire stitching) or unidirectional from right to left (e.g., with multiplexers performing wire stitching in the opposite direction as shown in FIG. 2). If desired, the wires in routing channel 280 may have any length. For example, the wires may have a length of two which may require wire stitching in every other functional block 260.

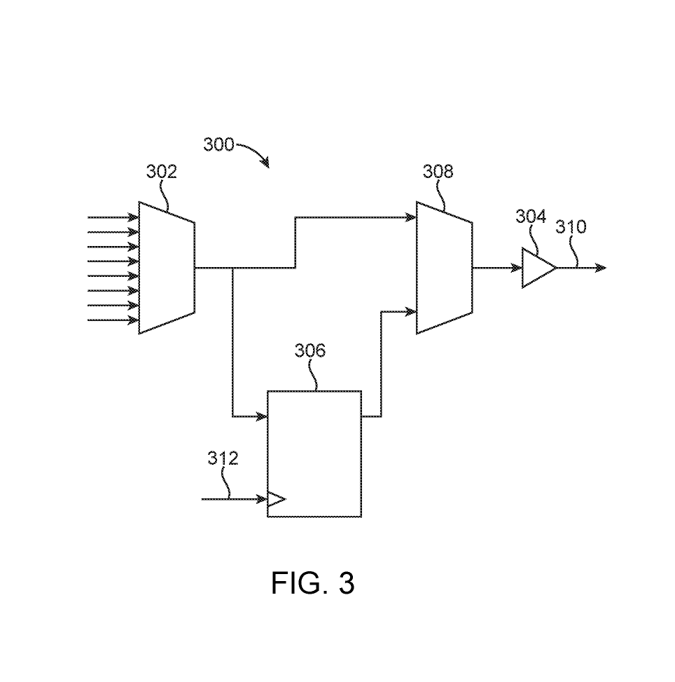

If desired, routing channel 280 may include pipeline circuits which are sometimes also referred to as pipeline elements. FIG. 3 depicts a configurable pipelined routing resource 300 which uses a register in accordance with an embodiment of the invention. As shown, the pipelined routing resource 300 includes a first multiplexer 302, a driver 304, a register 306, and a second multiplexer 308.

Multiplexer 302 may be a driver input multiplexer (DIM) or a functional block input multiplexer (FBIM). A DIM drives a routing wire 310 and may select from multiple sources that can drive the wire. The multiple sources may include signals from outputs of functional blocks and other routing wires that travel in the same or in an orthogonal direction to the wire. A FBIM outputs a signal to a functional block and may select the signal from multiple routing wires.

As shown in FIG. 3, in accordance with an embodiment of the invention, the multiplexer 302 may be pipelined by providing its output to the data input of register 306 (sometimes referred to herein as pipeline register 306). Multiplexer 308 in the pipelined routing resource 300 may receive the output of multiplexer 302 directly and may also receive the data output from register 306.

Although the pipelined routing resource 300 includes a register, it will be recognized by one skilled in the art that different circuits may be used to store a routing signal such as a pulse latch, a low-transparent latch, or a high-transparent latch, just to name a few. Thus, in order not to unnecessarily obscure the present embodiments, we may refer to the storage circuit in the pipelined routing resource as a memory element or a register.

Register 306 may store a routing signal based on a periodic control signal that register 306 may receive over wire 312. For example, register 306 may store a routing signal once during a period of the periodic control signal (e.g., at each rising edge of the periodic control signal) to accommodate a single data rate routing signal (i.e., the register operates in single data rate mode). As another example, register 306 may store a routing signal two times during a period of the periodic control signal (e.g., at each rising and each falling edge of the periodic clock signal) to accommodate a double data rate routing signal (i.e., the register operates in double data rate mode). If desired, register 306 may be configurable to operate either in single data rate mode or in double data rate mode.

Multiplexer 308 may enable the pipelined routing resource 300 to be either used in a non-pipeline mode or in a pipeline register mode. In the non-pipeline mode, the output of multiplexer 308 selects the direct output of multiplexer 302, thereby bypassing register 306.

In the pipeline mode, multiplexer 308 may select the output of register 306. Multiplexer 308 may provide its output to driver circuit 304, and the output of driver circuit 304 may be used to drive routing wire 310. Routing wire 310 may span multiple functional blocks (e.g., for a pipelined routing resource with a DIM). Alternatively, routing wire 310 may be inside a functional block (e.g., for a pipelined routing resource with a FBIM).

Every DIM/FBIM may include a register such as register 306 such that all the routing multiplexers are pipelined. However, in some embodiments, that may be unnecessary as the capabilities provided may exceed design requirements. Thus, in certain embodiments only a fraction, such as one-half or one-fourth, of the routing multiplexers may be pipelined. For example, a signal may take 150 picoseconds (ps) to traverse a wire of a given length, but a clock signal may be constraint to operate with a 650 ps clock cycle. Thus, providing a pipeline register such as register 306 every fourth wire may be sufficient in this example. Alternatively, the registers may be placed more frequently than every fourth wire (e.g., every second wire) to provide a higher degree of freedom in selection of which registers are used.

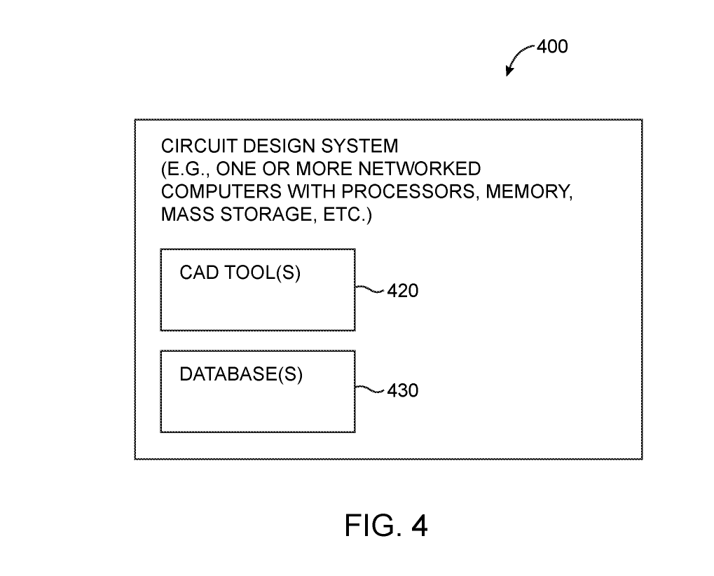

Computer-aided design (CAD) tools in a circuit design system may configure interconnect circuits such as interconnect circuits of FIG. 3, when implementing a circuit design on an integrated circuit. An illustrative circuit design system 400 in accordance with an embodiment is shown in FIG. 4. Circuit design system 400 may be implemented on integrated circuit design computing equipment. For example, system 400 may be based on one or more processors such as personal computers, workstations, etc. The processor(s) may be linked using a network (e.g., a local or wide area network). Memory in these computers or external memory and storage devices such as internal and/or external hard disks may be used to store instructions and data.

Software-based components such as computer-aided design tools 420 and databases 430 reside on system 400. During operation, executable software such as the software of computer aided design tools 420 runs on the processor(s) of system 400. Databases 430 are used to store data for the operation of system 400. In general, software and data may be stored on any computer-readable medium (storage) in system 400. Such storage may include computer memory chips, removable and fixed media such as hard disk drives, flash memory, compact discs (CDs), digital versatile discs (DVDs), Blu-ray discs (BDs), other optical media, and floppy diskettes, tapes, or any other suitable memory or storage device(s). When the software of system 400 is installed, the storage of system 400 has instructions and data that cause the computing equipment in system 400 to execute various methods (processes). When performing these processes, the computing equipment is configured to implement the functions of the circuit design system.

The computer aided design (CAD) tools 420, some or all of which are sometimes referred to collectively as a CAD tool, a circuit design tool, or an electronic design automation (EDA) tool, may be provided by a single vendor or by multiple vendors. Tools 420 may be provided as one or more suites of tools (e.g., a compiler suite for performing tasks associated with implementing a circuit design in a programmable logic device) and/or as one or more separate software components (tools). Database(s) 430 may include one or more databases that are accessed only by a particular tool or tools and may include one or more shared databases. Shared databases may be accessed by multiple tools. For example, a first tool may store data for a second tool in a shared database. The second tool may access the shared database to retrieve the data stored by the first tool. This allows one tool to pass information to another tool. Tools may also pass information between each other without storing information in a shared database if desired.

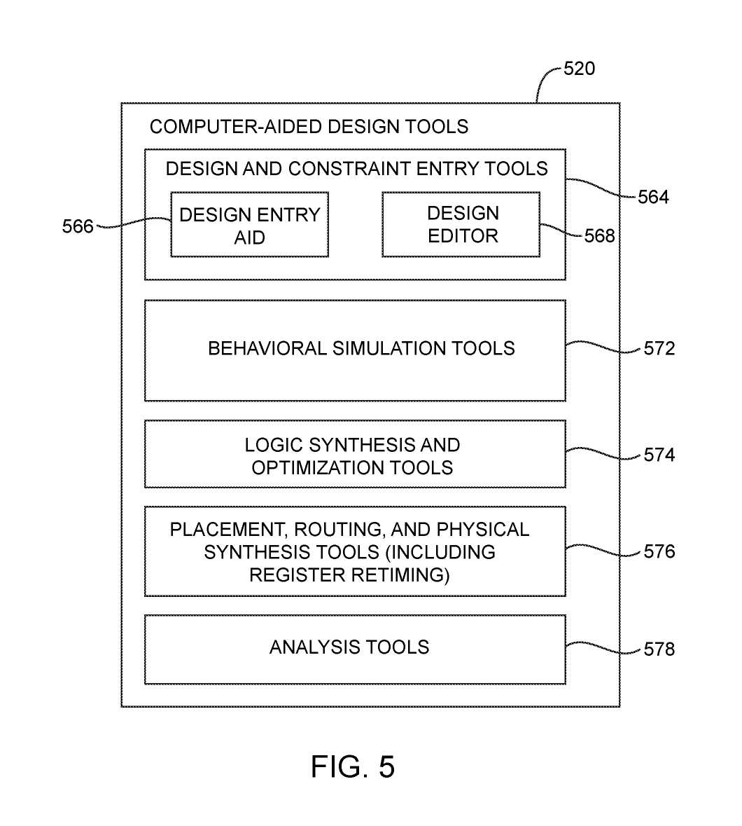

Illustrative computer aided design tools 520 that may be used in a circuit design system such as circuit design system 400 of FIG. 4 are shown in FIG. 5.

The design process may start with the formulation of functional specifications of the integrated circuit design (e.g., a functional or behavioral description of the integrated circuit design). A circuit designer may specify the functional operation of a desired circuit design using design and constraint entry tools 564. Design and constraint entry tools 564 may include tools such as design and constraint entry aid 566 and design editor 568. Design and constraint entry aids such as aid 566 may be used to help a circuit designer locate a desired design from a library of existing circuit designs and may provide computer-aided assistance to the circuit designer for entering (specifying) the desired circuit design.

As an example, design and constraint entry aid 566 may be used to present screens of options for a user. The user may click on on-screen options to select whether the circuit being designed should have certain features. Design editor 568 may be used to enter a design (e.g., by entering lines of hardware description language code), may be used to edit a design obtained from a library (e.g., using a design and constraint entry aid), or may assist a user in selecting and editing appropriate prepackaged code/designs.

Design and constraint entry tools 564 may be used to allow a circuit designer to provide a desired circuit design using any suitable format. For example, design and constraint entry tools 564 may include tools that allow the circuit designer to enter a circuit design using truth tables. Truth tables may be specified using text files or timing diagrams and may be imported from a library. Truth table circuit design and constraint entry may be used for a portion of a large circuit or for an entire circuit.

As another example, design and constraint entry tools 564 may include a schematic capture tool. A schematic capture tool may allow the circuit designer to visually construct integrated circuit designs from constituent parts such as logic gates and groups of logic gates. Libraries of preexisting integrated circuit designs may be used to allow a desired portion of a design to be imported with the schematic capture tools.

If desired, design and constraint entry tools 564 may allow the circuit designer to provide a circuit design to the circuit design system 400 using a hardware description language such as Verilog hardware description language (Verilog HDL), Very High Speed Integrated Circuit Hardware Description Language (VHDL), SystemVerilog, or a higher-level circuit description language such as OpenCL or SystemC, just to name a few. The designer of the integrated circuit design can enter the circuit design by writing hardware description language code with editor 568. Blocks of code may be imported from user-maintained or commercial libraries if desired.

After the design has been entered using design and constraint entry tools 564, behavioral simulation tools 572 may be used to simulate the functional performance of the circuit design. If the functional performance of the design is incomplete or incorrect, the circuit designer can make changes to the circuit design using design and constraint entry tools 564. The functional operation of the new circuit design may be verified using behavioral simulation tools 572 before synthesis operations have been performed using tools 574. Simulation tools such as behavioral simulation tools 572 may also be used at other stages in the design flow if desired (e.g., after logic synthesis). The output of the behavioral simulation tools 572 may be provided to the circuit designer in any suitable format (e.g., truth tables, timing diagrams, etc.).

Once the functional operation of the circuit design has been determined to be satisfactory, logic synthesis and optimization tools 574 may generate a gate-level netlist of the circuit design, for example using gates from a particular library pertaining to a targeted process supported by a foundry, which has been selected to produce the integrated circuit. Alternatively, logic synthesis and optimization tools 574 may generate a gate-level netlist of the circuit design using gates of a targeted programmable logic device (i.e., in the logic and interconnect resources of a particular programmable logic device product or product family).

Logic synthesis and optimization tools 574 may optimize the design by making appropriate selections of hardware to implement different logic functions in the circuit design based on the circuit design data and constraint data entered by the logic designer using tools 564. As an example, logic synthesis and optimization tools 574 may perform register retiming on the circuit design based on the length of a combinational path between registers in the circuit design and corresponding timing constraints that were entered by the logic designer using tools 564.

After logic synthesis and optimization using tools 574, the circuit design system may use tools such as placement, routing, and physical synthesis tools 576 to perform physical design steps (layout synthesis operations). Tools 576 can be used to determine where to place each gate of the gate-level netlist produced by tools 574. For example, if two counters interact with each other, tools 576 may locate these counters in adjacent regions to reduce interconnect delays or to satisfy timing requirements specifying the maximum permitted interconnect delay. Tools 576 create orderly and efficient implementations of circuit designs for any targeted integrated circuit (e.g., for a given programmable integrated circuit such as a field-programmable gate array (FPGA)).

Tools such as tools 574 and 576 may be part of a compiler suite (e.g., part of a suite of compiler tools provided by a programmable logic device vendor). In certain embodiments, tools such as tools 574, 576, and 578 may also include timing analysis tools such as timing estimators. This allows tools 574 and 576 to satisfy performance requirements (e.g., timing requirements) before actually producing the integrated circuit.

As an example, tools 574 and 576 may perform register retiming by moving registers through combinational logic (e.g., through logic AND, OR, XOR, and other suitable gates, look-up tables (LUTs), multiplexers, arithmetic operators, etc.). Tools 574 and 576 may push registers forward or backward across combinational logic. If desired, tools 574 and 576 may perform forward and backward pushes of registers by configuring pipelined routing resources such as pipelined routing resource 300 of FIG. 3 to operate in non-pipeline mode or as a pipelined routing element. Physical synthesis tools 576 used in this way can therefore also be used to perform register retiming.

After an implementation of the desired circuit design has been generated using tools 576, the implementation of the design may be analyzed and tested using analysis tools 578. For example, analysis tools 578 may include timing analysis tools, power analysis tools, or formal verification tools, just to name few.

After satisfactory optimization operations have been completed using tools 520 and depending on the targeted integrated circuit technology, tools 520 may produce a mask-level layout description of the integrated circuit or configuration data for programming the programmable logic device.

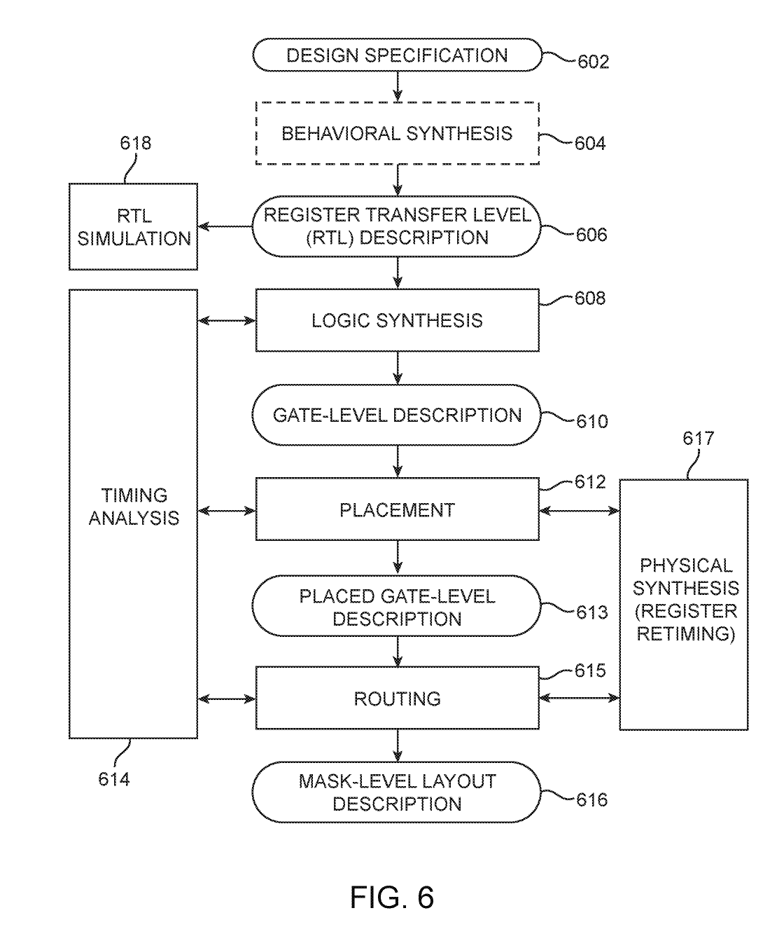

Illustrative operations involved in using tools 520 of FIG. 5 to produce the mask-level layout description of the integrated circuit are shown in FIG. 6. As shown in FIG. 6, a circuit designer may first provide a design specification 602. The design specification 602 may, in general, be a behavioral description provided in the form of an application code (e.g., C code, C++ code, SystemC code, OpenCL code, etc.). In some scenarios, the design specification may be provided in the form of a register transfer level (RTL) description 606.

The RTL description may have any form of describing circuit functions at the register transfer level. For example, the RTL description may be provided using a hardware description language such as the Verilog hardware description language (Verilog HDL or Verilog), the SystemVerilog hardware description language (SystemVerilog HDL or SystemVerilog), or the Very High Speed Integrated Circuit Hardware Description Language (VHDL). If desired, a portion or all of the RTL description may be provided as a schematic representation or in the form of a code using OpenCL, MATLAB, Simulink, or other high-level synthesis (HLS) language.

In general, the behavioral design specification 602 may include untimed or partially timed functional code (i.e., the application code does not describe cycle-by-cycle hardware behavior), whereas the RTL description 606 may include a fully timed design description that details the cycle-by-cycle behavior of the circuit at the register transfer level.

Design specification 602 or RTL description 606 may also include target criteria such as area use, power consumption, delay minimization, clock frequency optimization, or any combination thereof. The optimization constraints and target criteria may be collectively referred to as constraints.

Those constraints can be provided for individual data paths, portions of individual data paths, portions of a design, or for the entire design. For example, the constraints may be provided with the design specification 602, the RTL description 606 (e.g., as a pragma or as an assertion), in a constraint file, or through user input (e.g., using the design and constraint entry tools 564 of FIG. 5), to name a few.

At step 604, behavioral synthesis (sometimes also referred to as algorithmic synthesis) may be performed to convert the behavioral description into an RTL description 606. Step 604 may be skipped if the design specification is already provided in form of an RTL description.

At step 618, behavioral simulation tools 572 may perform an RTL simulation of the RTL description, which may verify the functional performance of the RTL description. If the functional performance of the RTL description is incomplete or incorrect, the circuit designer can make changes to the HDL code (as an example). During RTL simulation 618, actual results obtained from simulating the behavior of the RTL description may be compared with expected results.

During step 608, logic synthesis operations may generate gate-level description 610 using logic synthesis and optimization tools 574 from FIG. 5. If desired, logic synthesis operations may perform register retiming according to the constraints that are included in design specification 602 or RTL description 606. The output of logic synthesis 608 is gate-level description 610.

During step 612, placement operations using for example placement tools 576 of FIG. 5 may place the different gates in gate-level description 610 in a preferred location on the targeted integrated circuit to meet given target criteria (e.g., minimize area and maximize routing efficiency or minimize path delay and maximize clock frequency or any combination thereof). The output of placement 612 is placed gate-level description 613.

During step 615, routing operations using for example routing tools 576 of FIG. 5 may connect the gates from the placed gate-level description 613. Routing operations may attempt to meet given target criteria (e.g., minimize congestion, minimize path delay and maximize clock frequency or any combination thereof). The output of routing 615 is a mask-level layout description 616 (sometimes referred to as routed gate-level description 616).

While placement and routing is being performed at steps 612 and 615, physical synthesis operations 617 may be concurrently performed to further modify and optimize the circuit design (e.g., using physical synthesis tools 576 of FIG. 5). If desired, register retiming operations may be performed during physical synthesis step 617. For example, registers in the placed gate-level description 613 or the routed gate-level description 616 may be moved around according to the constraints that are included in design specification 602 or RTL description 606. As an example, register retiming operations may change the configuration of some pipelined routing resources (e.g., some instances of pipelined routing resource 300 of FIG. 3) from operating in pipeline register mode to operating in non-pipelined mode and the configuration of other pipelined routing resources (e.g., other instances of pipelined routing resources 300 of FIG. 3) from operating in non-pipelined mode to operating in pipeline register mode.

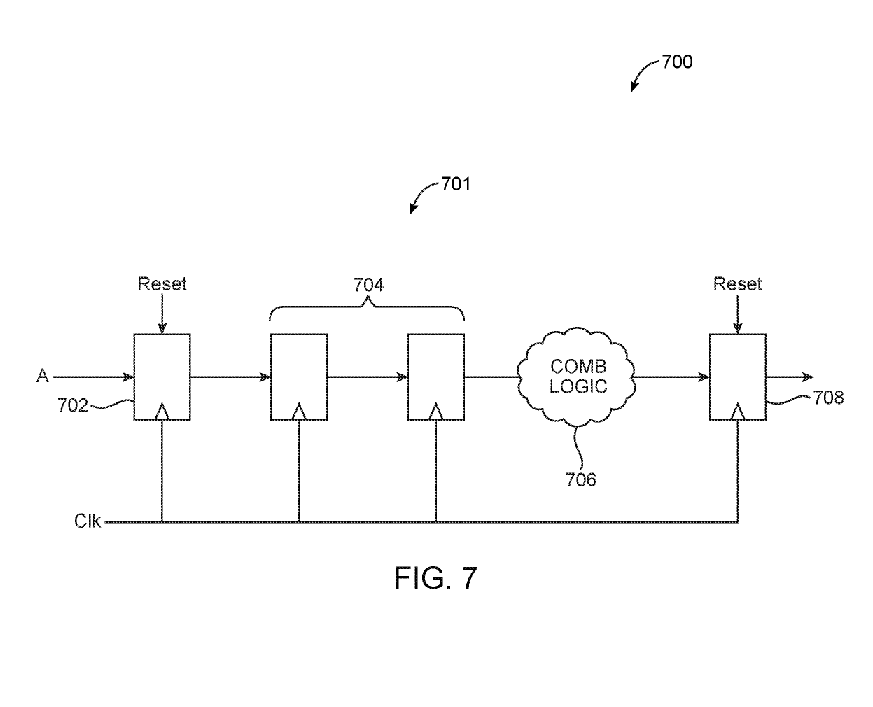

As an example, pipelined routing resources may operate completely in a pipeline register mode as shown in FIG. 7. FIG. 7 depicts simplified pipelined routing resources 701 that are operated completely in a pipeline register mode. Only pipeline registers 704 (sometimes referred to herein as “hyper” registers) are shown within the pipeline routing resources 701, where each register of pipeline registers 704 may correspond to a separate analogous pipeline register 306. Other analogous circuitry within pipelined routing resources 701 (e.g., circuitry analogous to multiplexers 302 and 308 and, driver 304 of FIG. 3) are omitted in FIG. 7 and hereinafter in order to avoid obscuring the present invention.

Pipeline registers 704 may propagate signals from an upstream element (e.g., register 702) to a downstream element (e.g., combinational logic 706). Although pipeline registers 704 includes only two pipeline registers, this is merely illustrative. Any desired number of pipeline registers may be used.

Register 702 may be a programmable reset register that includes a first input terminal for receiving signal Reset. Register 702 may include an input for a user-defined reset value. In contrast, pipeline registers 704 may completely or partially exclude reset functionalities because of the limited hardware resources and complexity associated with implementing such functionalities within pipelined routing resources. In a first scenario, in which a given pipeline register completely excludes reset functionalities, the given register may not be resettable (i.e., the register cannot be reset). In a second scenario, in which another given pipeline register partially excludes reset functionalities, the another given register may be resettable. However, the reset value, to which the another given register is reset, is fixed or non-programmable (e.g., reset value is always fixed at zero).

Register 702 may include a second input terminal that receives input data A for distribution to combinational logic 706 (sometimes referred to herein as combinatory logic 706). Input data A may propagate through pipeline registers 704 and ultimately reach combinational logic 706. Combinational logic 706 may include any desired logic circuitry (e.g., logic AND, OR, XOR, and other suitable gates, look-up tables (LUTs), multiplexers, arithmetic operators, etc.) Input data A may include configuration data used to configure combinational logic 706. If desired, input data A may include control data or any other type of suitable data for distribution to combinational logic 706.

Combinational logic 706 may generate an output data. The output data may be sent to register 708. Register 708 also be a programmable reset register. Register 708 may be part of an adjacent logic block. Alternatively, register 708 may further propagate the output data of combinational logic 706 to other combination logic within the same logic block. If desired, input data A may include configuration data used to configure another combinational logic. In such a scenario, input data A may propagate though combinational logic 706 without configuring combinational logic 706.

Programmable reset registers 702 and 708, and pipeline registers 704 may receive clock signal Clk with a clock cycle. Clock signal Clk may provide a synchronous clock signal with the same clock cycle to the corresponding registers. Input data A may propagate through pipeline registers 704 according to clock signal Clk (e.g., the clock cycle of clock signal Clk).

In an exemplary operation of integrated circuit 700, it may be desirable to reset combinational logic 706. When combinational logic 706 comes out of reset, combinational logic may require a known input value (e.g., a programmed reset value, a non-zero reset value). However, pipeline registers 704 upstream from combinational logic 706 may be unable to provide a reset value or may only be able to provide a reset value of 0. Both of which may be undesired in operating combinational logic 706 that comes out of reset. Resetting combinational logic 706 may occur during a global reset, and similarly during a power on, in which all previous configuration of any combinational logic within integrated circuit 700 may need to be reset. Resetting combinational logic 706 also may occur during a partial reset (e.g., partial reconfiguration, soft reset, etc.), in which previous configuration only for a partial section of integrate circuit 700 may be reset.

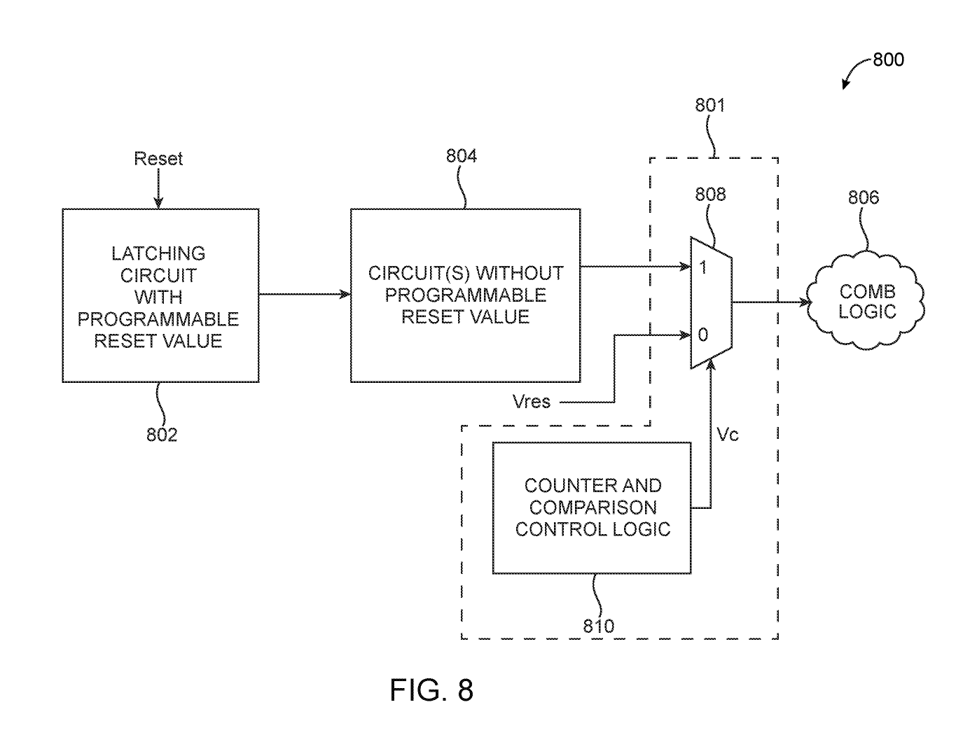

Reset control circuitry may be implemented within an integrated circuit to provide a desired reset value (e.g., a user-programmed reset value) to any combinational logic coming out of reset. FIG. 8 depicts integrated circuit 800 that includes reset control circuitry 801. FIG. 8 may further include latching circuitry with programmable reset value 802, circuitry without programmable reset value 804, and combinational logic 806 (similar to combinational logic 706).

Latching circuitry with programmable reset value 802 may, for example, be register 702 of FIG. 7. However, this is merely illustrative. If desired, latching circuitry with programmable reset value 802 may be any type of circuitry having set and reset capabilities configured with a programmable reset value.

Circuitry without programmable reset value 804 may, for example, be registers 704 of FIG. 7 (e.g., hyper pipeline registers). However, this is merely illustrative. If desired, circuitry without programmable reset value may be any type of circuit that does not have a reset input (e.g., circuitry that is not resettable).

To provide combinational logic with a programmable reset value, reset control circuitry 801 may be implemented between circuitry 804 and combinational logic 806 (e.g., downstream from circuitry 804 and upstream from combinational logic 806). Reset control circuitry 801 may include multiplexer 808 (sometimes referred to herein as reset control multiplexer 808) and counter and comparison control logic 810. Multiplexer 808 may include two input terminals, a control signal terminal and an output terminal. An output of circuitry 804 may be coupled to a first input of multiplexer 808. A reset value may be provided to a second terminal of multiplexer 808. The reset value may be the same reset value as the programmable reset value of circuitry 802. If desired, the reset value provided to multiplexer 808 may be any desired reset value (e.g., a known reset value for input into combinational logic 806 after complete or partial reset). The output terminal of multiplexer 808 is coupled to combinational logic 806 to provide the reset value to combinational logic 806.

In such a configuration, multiplexer may be said to “hold” a reset value. In other words, multiplexer 808 may hold the reset value at its second input until the reset value is distributed to combinational logic 806 (e.g., immediately after reset operations for combinational logic 806).

An output of counter and comparison control logic 810 is coupled to the control signal terminal of multiplexer 808. According to a path of circuitry 804, control logic 810 may store a value representing the length of the path of circuitry 804 (e.g., a path length value). The path length value may also be equivalent to the number of clock cycles it takes for data to propagate though the corresponding registers (e.g., based on the number of the corresponding registers. The path length may also be based on the number of maximum allowed corresponding registers (e.g., given some resource constraints). The path length value may be compared to a real-time value representing when a reset operation has taken place at circuitry 802. When the real-time value is greater than stored path length value, the output of multiplexer 808 may switch from the second input (e.g., input to provide combinational logic 806 with the desired reset value) to the first input. Reset control circuitry ensures that its output is always a known and valid input for combinational logic 806.

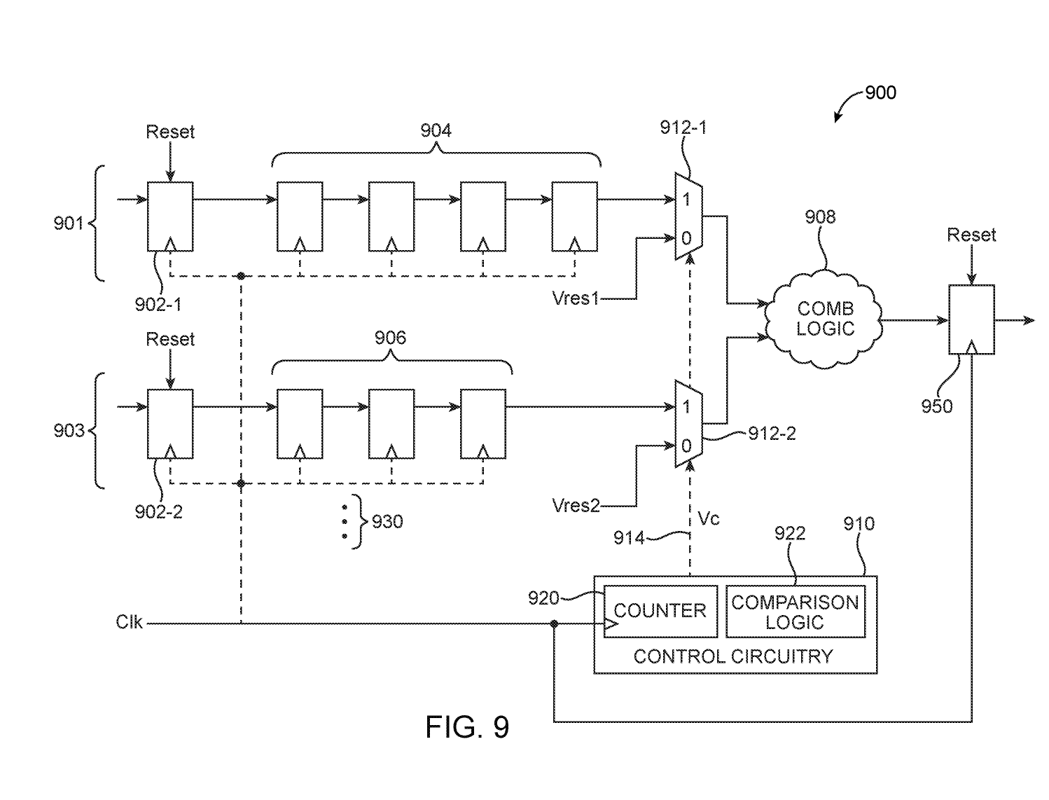

In an exemplary embodiment, combinational logic may have multiple paths (e.g., multiple data input paths) from which circuitry with programmable reset values may propagate their respective signals as shown in FIG. 9.

Combinational logic 908 coupled to paths 901 and 903 (sometimes referred to herein as data input paths or input data paths 901 and 903). Path 901 may include register 902-1, pipeline registers 904, and multiplexer 912-1 (sometimes referred to herein as reset control multiplexer 912-2). Register 902-1 may have be a register with a programmable reset value. In contrast with pipeline registers 904, which may include registers without a programmable reset value.

Pipeline registers 904 may include four pipeline registers. However, this is merely illustrative. If desired, any number of pipeline registers may be included within pipeline registers 904. For example, pipeline registers 904 may include, a single pipeline register, two pipeline registers, three pipeline register, or more than four pipeline registers.

Multiplexer 912-1 be coupled to an output of pipeline registers 904 at a first input and to reset value Vres1 at a second input. The reset value may be the same as the programmable reset value of register 902-1. An output of multiplexer 912-1 may be selected from one of its inputs. The output of multiplexer 912-1 may be controlled by control circuitry 910 though control signal Vc.

Path 903 may include register 902-2, pipelined registers 906, and multiplexer 912-2. Register 902-2 may have be a register with a programmable reset value. In contrast with pipeline registers 906, which may include registers without a programmable reset value.

Pipeline registers 906 may include three pipeline registers. However, this is merely illustrative. If desired, any number of pipeline registers may be included within pipeline registers 906. For example, pipeline registers 906 may include, a single pipeline register, two pipeline registers, three pipeline register, or more than four pipeline registers.

Multiplexer 912-2 (sometimes referred to herein as reset control multiplexer 912-2) may be coupled to an output of pipeline registers 906 at a first input and to reset value Vres2 at a second input. The reset value may be the same as the programmable reset value of register 902-2. An output of multiplexer 912-2 may be selected from one of its inputs. The output of multiplexer 912-2 may also be controlled by control circuitry 910 through control signal Vc.

Combinational logic 908 coupled to two paths (e.g., paths 901 and 903) is merely illustrative. As indicated with ellipses 930, any number of paths may be coupled to combinational logic 908. For example, one path may be coupled to combinational logic 908, three paths may be coupled to combinational logic 908, or greater than three paths may be coupled to combinational logic 908. Each path may include its own latching circuitry with programmable reset value, its own circuitry without programmable reset value, and its own multiplexer as part of reset control circuitry. Each input data path may be configured to serially process single bits or multiple bits in parallel (e.g., a plurality of bits encoded on a multibit bus). The respective circuitry without programmable reset value of each path may include circuitry of various path lengths (e.g., various numbers of individual registers, pipeline registers, hyper pipeline registers, etc.). The respective multiplexers of every path may be control by a single control circuitry (e.g., control circuitry 910).

Control circuitry 910 may include counter 920 and comparison logic 922. Counter 920 may be any circuitry that stores how many clock cycles have elapsed. As an example, counter 920 may include multiple flip-flops coupled with each other. Counter 920 may also include any type of logic circuitry (e.g., AND gates, NAND gates, etc.). Comparison logic 922 may be any circuitry that can compare two numbers from two inputs. As an example, comparison logic 922 may be a digital comparator that takes two inputs in binary form and determine one of the two inputs is greater than, less than, or equal to the other input. If desired, comparison logic 922 may include multiple XNOR gates that compares each bit of the two input binary numbers. However, this is merely illustrative. Comparison logic 922 may include more complex circuitry that may include any type of logic circuitry (e.g., any type digital gate circuitry, multiplexers, etc.)

When operating control circuitry 901 to provide a reset value to combinational logic 908, a longest path length may be determined from the multiple data input paths coupled to combinational logic 908. In FIG. 9, path 901 has a path length of four, determined by the number of registers within pipeline registers 904 or by the number of cycles need to propagate though the corresponding registers. Path 903 has a path length of three. As an example, if a path includes one register within a group of pipeline registers, the corresponding path length may be one. As an example, if a path includes ten registers, within a group of pipeline register, the corresponding path length may be ten.

The longest path length may be the largest path length of any of respective input date paths coupled to a combinational logic that shares a single counter. When the longest path length is determined (e.g., the longest path length is determined to be four in the exemplary embodiment of FIG. 9), the longest path length may be stored in memory (not shown) within control circuitry 910. After a reset operation (e.g., partial reconfiguration, global reset, start-up) of combinational logic 908, desired reset values may be provided to combinational logic 908 using reset control multiplexers (e.g., multiplexers 912-1 and 912-2). Counter 920 may be initiated to count a number of clock signals indicative of the amount of time a data signal has already taken to propagate through pipeline registers (e.g., pipeline register 904 and 906). For example, after the data signal has propagated a single pipeline register (e.g., after a single clock cycle), counter 922 may store a counter value of one. For example, after the reset signal has propagated through two pipeline registers, counter 922 may store a counter value two.

Comparison logic 922 may compare the stored longest path value (sometimes referred to herein as the predetermined number of clock cycles) with the counter value, after every state change of the counter value. If the counter value is less than the stored longest path value, control signal Vc may provide a value of zero to reset control multiplexers. If the counter value is greater than or equal two the stored longest path value, control signal Vc may provide a value of one to reset control multiplexers.

For example, in FIG. 9, the stored longest path value is four. When the counter value stored at counter 920 is less than four, control signal Vc provides a value of zero to multiplexers 912-1 and 912-2. When the counter value stored at counter 920 is equal to four or greater than four, control signal Vc provides a value of one to multiplexers 912-1 and 912-2. When a value of zero is provided to multiplexers 912-1 and 912-2, the outputs of multiplexers 912-1 and 912-2 may be respectively reset values Vres1 and Vres2. The reset values Vres1 and Vres2 (e.g., programmable reset values, user-defined reset values, valid reset values) may be provided to combinational logic 908.

Register 950 may function analogously to registers 902-1 and 902-2. Register 950 may receive an input from combinational logic 908 and propagate the input from combinational logic 908 to other combinational logic through other pipeline circuits (e.g., pipeline registers).

Each register may receive clock signal Clk. Clock signal Clk may include a synchronous clock cycle provided to propagate signals through the multiple paths to combinational logic 908. Clock signal Clk may also be provided to register 950, which may further propagate an output of combinational logic 908 to other logic circuitry within the same logic block or in other logic blocks. Clock signal Clk may also be provided to counter 920. Counter 920 may interpret a clock cycle of clock signal Clk (e.g., each rising edge and/or falling edge of clock signal Clk) as a trigger event for propagation though pipeline registers 904 or 906. This is merely illustrative. Any other suitable counting scheme may be used to determine propagation through pipeline registers.

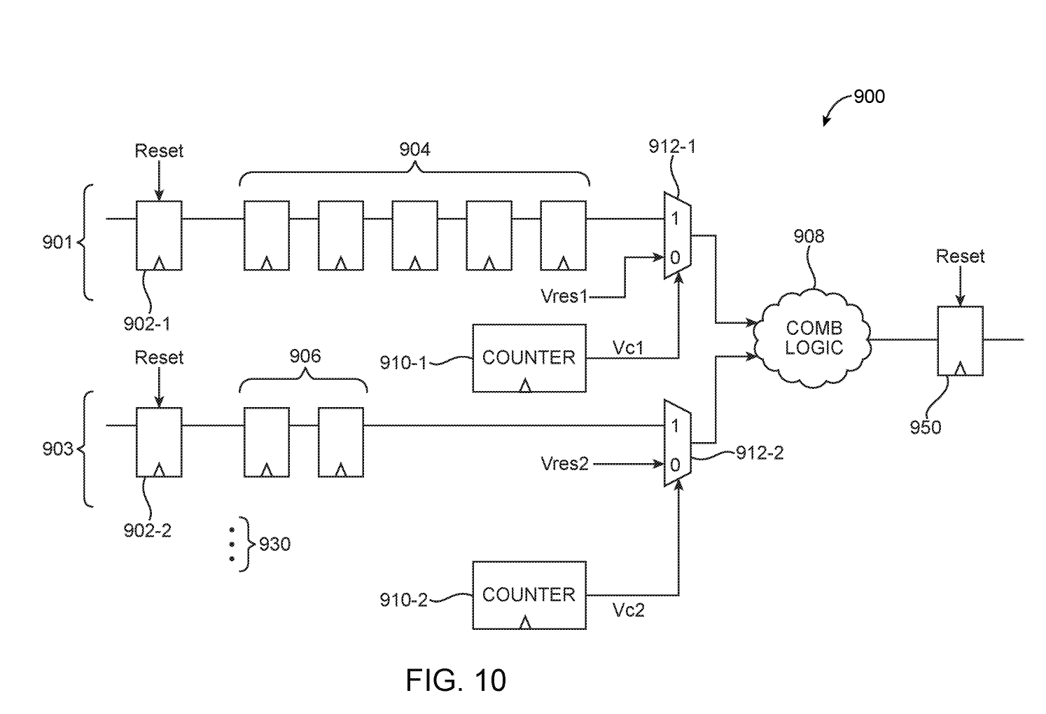

In an exemplary embodiment of the present invention, reset control multiplexers on multiple paths may each be controlled by a dedicated counter as shown in FIG. 10. Counter 910-1 may be dedicated to path 901. In this configuration. Counter 910-1, memory within counter 910-1, or memory external to counter 910-1 may store the path length of path 901 (e.g., a path length of five determined by the number of pipeline registers or by the number of clock cycles need to propagate a signal though the pipeline registers). Counter 910-2 may be dedicated to path 901. Counter 910-2, memory within counter 910-1, or memory external to counter 910-2 may store the path length of path 903 (e.g., a path length of two).

Some details discussed previously in connection with FIG. 9 are omitted in order to not obscure the details of the present embodiment. In other words, the counting and comparison operations as described in connection with FIG. 9 may be implemented independently for each individual path.

As an example, counter 910-1 may use an input clock signal (e.g., clock signal Clk in FIG. 9) to count a number of pipeline registers (e.g., a number of steps) a reset signal has propagated though and store the number of signal propagation steps as a counter value. For example, after a first trigger event (e.g., a first rising edge or any event that cause propagation through a register of pipeline registers 904) of a clock signal, the counter value may be “001” in binary. The counter value (currently “001” may be compared to the stored path length value for path 901, which is “101” in binary.

The comparison may be done on a global comparison logic, a comparison logic dedicated for reset control circuitry (e.g., comparison logic 922 in FIG. 9), a comparison logic dedicated to combinational logic 908, or any other types of comparison logic. The comparison may compare the location of the most significant bit of the counter value to the location of the most significant bit of the stored path length value. The comparison logic may only need to determine whether the counter value is smaller than the stored path length value, or not. However, this is merely illustrative. If desired, any type of comparison schemes may be used. Since the counter value is smaller than the stored path length value, control signal Vc1 may provide a value of zero to multiplexer 912-1. Control signal Vc1 may be provided by counter 910-1 or by a corresponding comparison logic circuit (not shown in FIG. 10).

Subsequently, after a second trigger event (e.g., a first falling edge, a second rising edge, etc.) of the clock signal, the counter value may be “010” in binary. This counter value may again be compared to the stored path length value. Since the counter value is still smaller than the stored path length value, control signal Vc1 may provide a value of zero to multiplexer 912-1.

After the fifth trigger event, the counter value may be “101” in binary. After comparison, the counter value may be determined to be equal to the stored path length value of “101”. Since the counter value is equal to the stored path length value, control signal Vc1 may provide a value of one to multiplexer 912-1.

After any subsequent trigger events after the fifth trigger event, the counter value will be greater than the stored path length value. Therefore, control signal

Vc1 may continue to provide a value of one to multiplexer 912-1.

Circuitry corresponding to path 903 may operate similarly to the operation of circuitry corresponding to path 901 as previously discussed. However, the stored path length value for path 903 may be equal to “010” in binary. As a result, comparisons in path 903 use “010” as the stored path length value. Control signal Vc2 may be provided to multiplexer 912-2 by counter 910-2 or by a corresponding comparison logic circuit (not shown in FIG. 10).

The exemplary embodiments of FIGS. 9 and 10 may be both simultaneously implemented within integrated circuity 900 if desired. In these embodiments, any number of registers may be used within the corresponding pipeline register circuitry. In addition, any number of paths may be coupled to combinational logic and each path may include any number of registers within its corresponding pipeline register circuitry. If desired, some paths may share counter circuitry and comparison circuitry. If desired, some paths may only share counter circuitry. If desired some paths may each have dedicated counter and comparison circuitry.

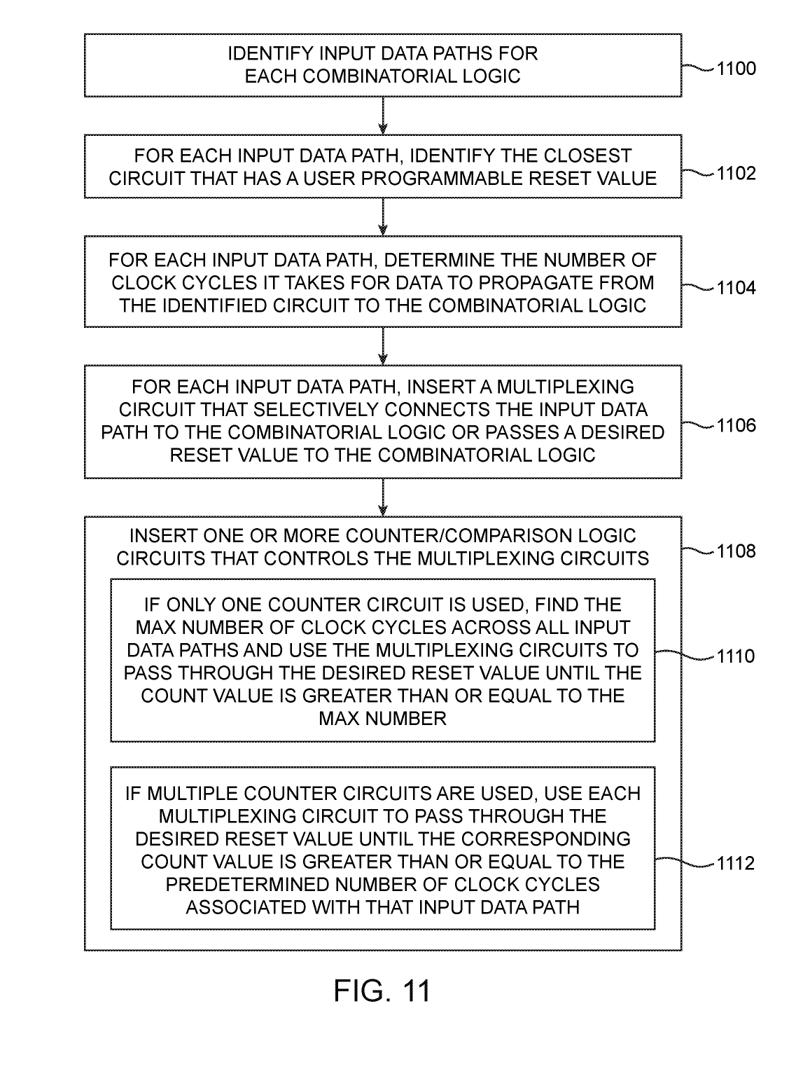

FIG. 11 depicts a flow chart showing illustrative steps for configuring and operating reset control circuitry (as shown previously in FIGS. 8-10) within an integrated circuit.

To correctly and efficiently synthesize reset control circuitry, information may be collected about the pipelined interconnect circuitry. At step 1100, using CAD tools, input data paths for each combinational logic may be identified. For example, circuitry 804 in FIG. 8 may include a single path or multiple parallel paths connected to combinational logic 806. A path within circuitry 804 may be identified at step 1100. Any other paths, if present, within circuitry 804 may also be identified. Similar operations may identify respective paths for other combinational logic within integrated circuit 800. In a more specific example, paths 901 and 903 for combinational logic 908 of FIGS. 9 and 10 may be identified. Any additional paths as indicated by ellipses 930 may also be identified. The paths for multiple combinational logic circuitry within an integrated circuit be may identified recursively. However, this is merely illustrative.

At step 1102, for each input data path, a closest circuit with a user programmable reset value may be identified. For example, latching circuitry 802 may be identified as the closest circuit with a user programmable reset value corresponding a given input data path within circuitry 804. In a more specific example, register 902-1 may be the closest circuit with a user programmable reset value corresponding to input data path 901. In another specific example, register 902-2 may be the closest circuit with a user programmable reset value corresponding to input data path 903.

At step 1104, for each input data path, the number of clock cycles it takes for data to propagate from the identified circuit to the combinational logic may be determined. For example, a given number of clock cycles may be needed to propagate a signal from circuitry 802 to combinational logic 806 in FIG. 8. The given number of clock cycles may be determined by examining circuitry 804.

In a more specific example, in FIG. 9 a number of clock cycles it takes for data to propagate from register 902-1 to combinational logic 908 may be determined to be four. As discussed previously, the number of clock cycles it takes for data to propagate from register 902-1 to combinational logic 908 may also be based on a number of registers within pipeline circuitry 904.

At step 1106, for each input data path, a multiplexing circuit that selectively connects the input data path to the combinational logic or passes a desired reset value to the combinational logic may be inserted. For example, multiplexers 808, 912-1, and 912-2 may all be configured to couple either an input data path or a desired reset value (e.g., respectively Vres, Vres1, and Vres2) to combinational logic 806 in FIG. 8 or 908 in FIG. 9.

At step 1108, one or more counter and/or comparison logic circuits that control the multiplexer circuits may be inserted. However, the number and configuration of counter and comparison logic circuits may be determined based on an application of the integrated circuit. Since every combinational logic within a given integrate circuit may be coupled to a large number of input data paths, too much resources may be used if dedicated counters and comparison logic circuits are used for every path.

Alternatively, if all paths shared a single counter and a single comparison logic circuit, the longest path constrains operations. In other words, the efficiency of operations is limited by the longest path, since communications of a shorter path may be delayed, since all timing correspond to the longest path. If desired, a combination of both may be implemented in various sections of the integrated circuit. In other words, both steps 1110 and 1112 may be taken within the integrated circuit to implement the reset control circuit in respective parts of the integrated circuit. This is merely illustrative. If desired, either step 1110 or step 1112 may be taken.

Step 1108 may include step 1110. At step 1110, if only one counter circuit is used, the maximum number of clock cycles across all input data paths that share the one counter circuit is found and the multiplexing circuits may pass though the desired reset value until the count value is greater than or equal to the maximum number. For example, FIG. 9 shows paths 901 and 903 sharing counter 920.

Step 1108 may further include step 1112. At step 1112, if multiple counter circuits are used, each multiplexing circuit may pass though the desired reset value until the corresponding count value is greater than or equal to the predetermined number of clock cycles associated with that input data path. For example, FIG. 10 shows paths 901 and 903 respectively having dedicated counters 910-1 and 910-2. Counters 910-1 and 910-2 have their respective counter values and stored path length values that are compared independently.

Steps to synthesize and configure corresponding circuitry related to reset control circuitry may be implemented in software in an automatic manner to simplify user experience. In other words, the synthesis and configuration of reset control circuitry may be hidden from users or designers.

The synthesis and configuration steps (e.g., steps 1100-1112) may be implemented during synthesis steps during logic circuit design (e.g., during step 608 in FIG. 6). This is merely illustrative, if desired, steps 1100-1112 may be implemented during any other steps of logic circuit design after RTL Description (e.g., after step 606 in FIG. 6). For example, steps 1100-1112 may be implemented during fitting (e.g., placement, during step 612 in FIG. 6), routing (e.g., during step 615 in FIG. 6), or retiming (e.g., during step 617 in FIG. 6).

The method and apparatus described herein may be incorporated into any suitable electronic device or system of electronic devices. For example, the method and apparatus may be incorporated into numerous types of devices such as microprocessors or other ICs. Exemplary ICs include programmable array logic (PAL), programmable logic arrays (PLAs), field programmable logic arrays (FPLAs), electrically programmable logic devices (EPLDs), electrically erasable programmable logic devices (EEPLDs), logic cell arrays (LCAs), field programmable gate arrays (FPGAs), application specific standard products (ASSPs), application specific integrated circuits (ASICs), digital signal processors (DSPs), graphics processing units (GPUs) just to name a few.

The programmable logic device can be used to perform a variety of different logic functions. For example, the programmable logic device can be configured as a processor or controller that works in cooperation with a system processor. The programmable logic device may also be used as an arbiter for arbitrating access to a shared resource in the data processing system. In yet another example, the programmable logic device can be configured as an interface between a processor and one of the other components in the system. In one embodiment, the programmable logic device may be one of the family of devices owned by ALTERA/INTEL Corporation.

The integrated circuit described herein may be part of a data processing system that includes one or more of the following components; a processor; memory; I/O circuitry; and peripheral devices. The integrated circuit can be used in a wide variety of applications, such as computer networking, data networking, instrumentation, video processing, digital signal processing, or any suitable other application where the advantage of using interconnection circuits that provide reset value holding capabilities is desirable.

Although the method operations were described in a specific order, it should be understood that other operations may be performed in between described operations, described operations may be adjusted so that they occur at slightly different times or described operations may be distributed in a system which allows the occurrence of the processing operations at various intervals associated with the processing, as long as the processing of the overlay operations are performed in a desired way.

The foregoing is merely illustrative of the principles of this invention and various modifications can be made by those skilled in the art without departing from the scope and spirit of the invention.

What is claimed is:

1. An integrated circuit, comprising:
logic circuitry; and
a switching circuit that selectively provides a selected one of a reset signal and a data signal to the logic circuitry.

2. The integrated circuit of claim 1, wherein the switching circuit comprises a multiplexer.

3. The integrated circuit of claim 1, further comprising:
a latching circuit having a programmable reset value that feeds the data signal to the switching circuit.

4. The integrated circuit of claim 3, further comprising:
a circuit without a programmable reset value interposed between the latching circuit and the switching circuit.

5. The integrated circuit of claim 4, wherein the circuit has a fixed reset value.

6. The integrated circuit of claim 4, wherein the circuit cannot be reset.

7. The integrated circuit of claim 4, wherein the latching circuit comprises a register.

8. The integrated circuit of claim 7, wherein the circuit comprises at least one pipeline register.

9. The integrated circuit of claim 1, further comprising:
control logic for controlling the switching circuit.

10. The integrated circuit of claim 1, wherein the control logic includes a counter circuit.

11. A method for operating an integrated circuit, comprising:
with a first switching circuit, receiving a signal from a first input path and a first reset signal;
with a control circuit, receiving a clock signal and configuring the first switching circuit to pass through the first reset signal for a predetermined number of clock cycles; and
after passing the first reset signal through the first switching circuit for the predetermined number of clock cycles, configuring the first switching circuit to instead pass through the signal from the first input path.

12. The method of claim 11, further comprising:
with a second switching circuit, receiving a signal from a second input path and a second reset signal;
with the control circuit, configuring the second switching circuit to pass through the second reset signal for the predetermined number of clock cycles; and
after passing the second reset signal through the second switching circuit for the predetermined number of clock cycles, configuring the second switching circuit to instead pass through the signal from the second input path.

13. The method of claim 11, further comprising:
with a second switching circuit, receiving a signal from a second input path and a second reset signal;
with the control circuit, configuring the second switching circuit to pass through the second reset signal for a given number of clock cycles that is different than the predetermined number of clock cycles; and
after passing the second reset signal through the second switching circuit for the given number of clock cycles, configuring the second switching circuit to pass through the signal from the second input path.

14. The method of claim 11, further comprising:
with the control circuit, counting the number of clock cycles that have elapsed for the clock signal.

15. The method of claim 14, further comprising:
with the control circuit, comparing the count to the predetermined number of clock cycles.

16. An integrated circuit, comprising:
combinational logic;
a first register with a programmable reset value;
a first multiplexer that receives signals from the first register and that also receives a first predetermined reset value; and
a first circuit that is interposed between the first register and the first multiplexer and that lacks a programmable reset value.

17. The integrated circuit of claim 16, further comprising:
a second register with a programmable reset value;
a second multiplexer that receives signals from the second register and that also receives a second predetermined reset value; and
a second circuit that is interposed between the second register and the second multiplexer and that lacks a programmable reset value.

18. The integrated circuit of claim 16, wherein the first circuit includes configurable pipelined routing resources.

19. The integrated circuit of claim 18, wherein the configurable pipelined routing resources comprise a plurality of series-connected pipeline registers.

20. The integrated circuit of claim 16, further comprising:
a counter that controls the first multiplexer.
